(19) United States
(12) Patent Application Publication
(10) Pub. No.: US 2005/0133886 A1
(43) Pub. Date: Jun. 23, 2005

(54) Integrated circuit for differential variable capacitors

(76) Inventors: Felix Kao, Taipei (TW); Bouryi Sze, Taipei (TW)

Correspondence Address: BIRCH STEWART KOLASCH & BIRCH, PO BOX 747, FALLS CHURCH, VA, 22040-0747, US

(21) Appl. No.: 10/780,712

(22) Filed: Feb. 19, 2004

(30) Foreign Application Priority Data
Dec. 23, 2003 (TW) 92136464

(51) Int. Cl. H01L 29/00

(52) U.S. Cl. 257/534

(57) ABSTRACT

An integrated circuit design for differential variable capacitors uses an integration method to integrate an integrated circuit having differential variable capacitors as a whole, and takes the parasitic effect into consideration for the manufacturing process to lower the circuit inaccuracy and reduce the chip size effectively. Such arrangement lowers the manufacturing cost, identifies the quality of loading quality of the overall variable capacitance during the manufacture, and further controls the quality of loading capacity of the overall variable capacitance effectively. Furthermore, this invention does not need to reposition for the symmetrical position of the coils, and thus giving a very precise positioning to reduce the level of difficulty for the manufacture.

### 1. FIELD OF THE INVENTION

The present invention relates to an integrated circuit design for differential variable capacitors, more particularly to an integrated circuit being integrated with differential variable capacitors and having no asymmetric coil for reducing the chip size, lowering the circuit inaccuracy, and controlling the overall loading quality of variable capacitors effectively.

### 2. BACKGROUND OF THE INVENTION

A voltage control oscillator (VCO) is an important circuit indispensable to the applications of radio frequency (RF)/microwave and wireless communication, which uses a bias voltage to enable the variable capacitor therein to vary its capacitance, and thus further changes the oscillating frequency.

More and more people adopt differential circuit design for the circuit of voltage control oscillators (VCO) to reduce the interference caused by common-mode noises. To achieve the differential effect, differential variable capacitors become an essential component. However, the conventional differential variable capacitor usually consists of two independent capacitors, and such arrangement not only increases the chip size, but also enhances a circuitry inaccuracy due to the parasitic effect occurring between the two independent capacitors.

As seen in FIGS. 1A and 1B, a conventional differential variable capacitor is consisted of a first capacitor 1 and a second capacitor 2. The circuit design of the conventional differential variable capacitor is as following: respectively forming n+ implant points 12, 22 in n-well regions 11, 21 on p-substrates 10, 20; connecting the n+ implant points 12, 22 to form a bias voltage control point Vc; employing P1 and P2 as the contacts for connecting to other circuits; and employing p+ implant points 13, 23 as the grounding point.

In view of the circuit design of the conventional differential variable capacitor, there exists at least the following shortcomings:
1. The conventional differential variable capacitor adopts two independent capacitors. Therefore, a larger chip is required for the making of the differential variable capacitor such that the manufacturing cost is increased.
2. Parasitic effects will occur at the connection between the two independent variable capacitors of the conventional differential variable capacitor, and thus increasing the circuitry inaccuracy.
3. Since the connection between two variable capacitors must be symmetrical, therefore the positioning has to be very precise, and thus increasing the level of difficulty of the manufacture.
4. Asymmetry usually occurs in the connection between the two variable capacitors, and thus greatly reducing the differential effect.
5. In the conventional differential variable capacitor, there is no way of knowing the factor of overall loading quality of the variable capacitor.

### SUMMARY OF THE INVENTION

In view of the shortcomings of the prior arts, the primary object of the present invention is to provide an integrated circuit design of a differential variable capacitor, using an integrated method to design an integrated circuit of a differential variable capacitor with the consideration of solving the parasitic effect occurred therein so as to reduce the circuitry inaccuracy.

Another object of the present invention is to provide an integrated circuit design of a differential variable capacitor, using an integrated method to design an integrated circuit of a differential variable capacitor to effectively reduce the chip size and lower the manufacturing cost.

Yet, another object of the present invention is to provide an integrated circuit design of a differential variable capacitor, using an integrated method to design an integrated circuit of a differential variable capacitor to prevent the happening of asymmetric coils.

Yet, another object of the present invention is to provide an integrated circuit design of a differential variable capacitor, capable of knowing the factor of overall loading quality of the variable capacitors, and thus further effectively controlling the overall loading quality of the variable capacitors.

Yet, another object of the present invention is to provide an integrated circuit design of a differential variable capacitor, which is integrally formed without the need of repositioning for achieving a symmetrical connection, and thus has a very precise positioning so as to reduce the level of difficulty of manufacturing the same.

To achieve the foregoing objectives, the present invention provides an integrated circuit design of a differential variable capacitor, which comprises: a p-substrate; an n-well region disposed on the top surface of the p-substrate; at least three n-type ion implant regions, each disposed on the top surface of the n-well region; a metal wire for connecting the three n-type ion implant regions; a bias voltage control point, coupled to the n-type ion implant region; a first gate; and a second gate being coupled with the first gate; wherein the first gate and second gate use the bias control point as center to be disposed symmetrically on both sides of the bias voltage control point. Therefore, the integrated circuit uses an integrated design to integrally form the differential variable capacitor, and the parasite effect is also taken into consideration in the manufacturing process for reducing the circuitry inaccuracy, lowering the manufacturing cost, and preventing asymmetric coils from happening. The present invention provides the knowledge about the factor of overall loading quality of the variable capacitors, and thus further effectively controls the overall loading quality of the variable capacitors during manufacturing the same. Furthermore, the present invention does not require repositioning for the symmetric connection, and thus has a very precise positioning so as to reduce the level of difficulty of manufacturing the same.

### BRIEF DESCRIPTION OF THE DRAWINGS

FIG. 1A is a top view of a conventional differential variable capacitor.

FIG. 1B is a cross-sectional view of a conventional differential variable capacitor.

FIG. 2A is a top view of a differential variable capacitor according to a first preferred embodiment of the present invention.

FIG. 2B is a cross-sectional view of a differential variable capacitor according to a first preferred embodiment of the present invention.

FIG. 3A is a top view of a differential variable capacitor according to a second preferred embodiment of the present invention.

FIG. 3B is a cross-sectional view of a differential variable capacitor according to a second preferred embodiment of the present invention.

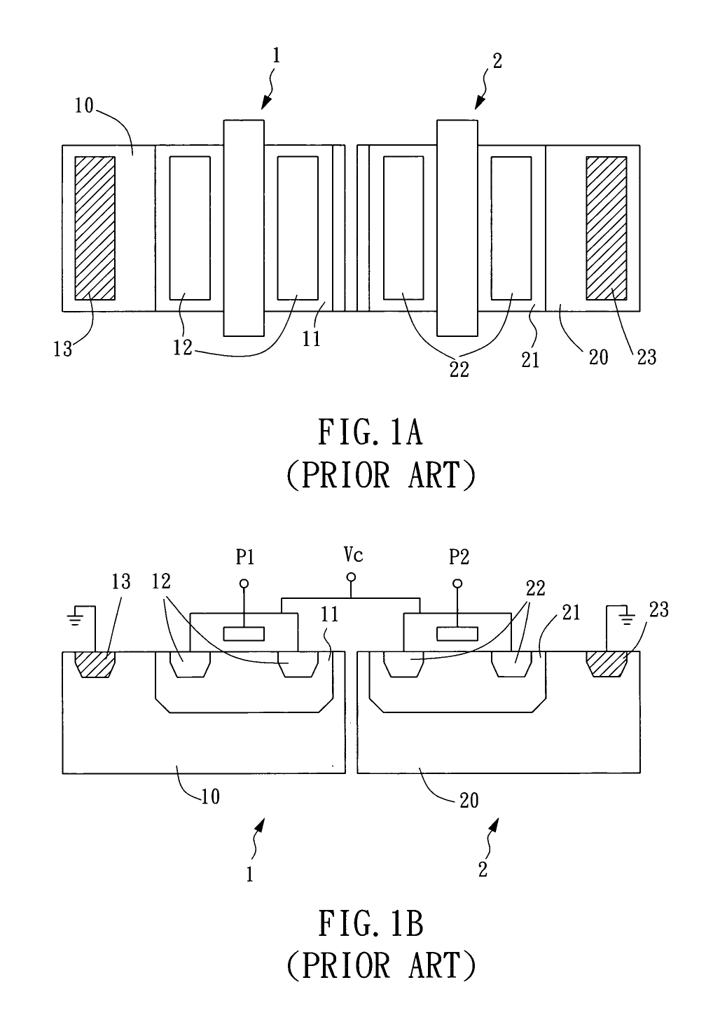

### DESCRIPTION OF THE PREFERRED EMBODIMENT

For your esteemed members of reviewing committee to further understand and recognize the objectives, the characteristics, and the functions of the invention, a detailed description in matching with corresponding drawings are presented as the following.

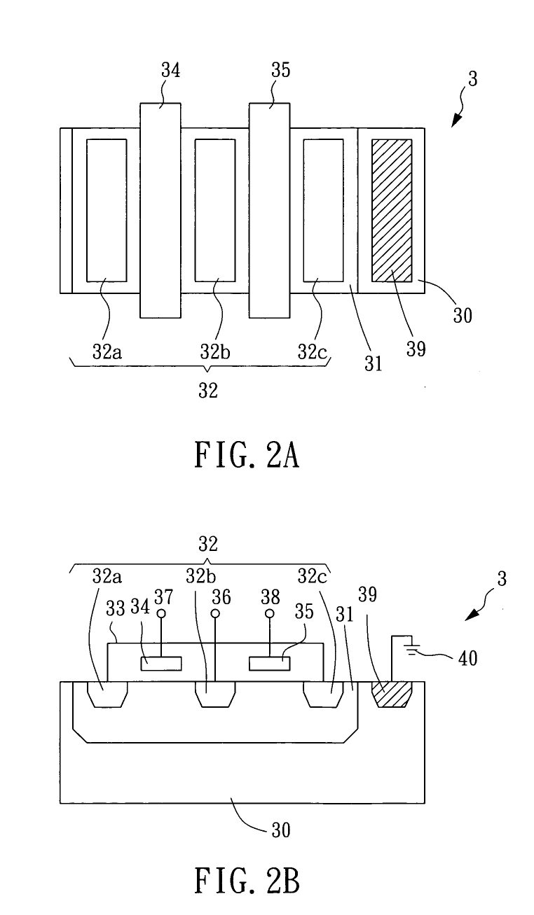

Please refer to FIGS. 2A and 2B for the top view and cross-sectional view of a preferred embodiment of the present invention respectively, wherein the integrated circuit of a differential variable capacitor 3 forms an n-well 31, using an ion implant method to implant at least three n-type ion implant regions 32 disposed on the top surface of the n-well. The n-type ion implant regions 32 include a first n-type ion implant region 32a, a second n-type ion implant region 32b, and a third n-type ion implant region 32c; wherein the first n-type ion implant region 32a and the third n-type ion implant region 32c use the second n-type ion implant region 32b as the center to be disposed symmetrically on both sides of the second n-type ion implant region 32b. Since the relative positions of the first n-type ion implant region 32a, second n-type ion implant region 32b, and third n-type ion implant region 32c can be confirmed in the ion implantation, so that the differential variable capacitor 3 is designed as a whole, which no longer needs to reposition for the symmetric connection.

The conventional lithographic and etching technologies are used to form a structure using the contact point of an oxide layer to connect the connecting points and metal wire; wherein the metal wire 33 connects the foregoing n-type ion implant region 32b; the first gate 34 is disposed in the metal wire 33 and between the first n-type ion implant region 32a and the second n-type ion implant region 32b; the second gate 35 is also disposed in the metal wire 33 and between the second n-type ion implant region 32b and the third n-type ion implant region 32c; the bias voltage control point 36 is coupled to the first n-type ion implant region 32a, the second n-type ion implant region 32b, and the third n-type ion implant region 32c; the first contact point 37 is coupled to the first gate 34; the second connecting point 38 is coupled to the second gate 35, wherein the first connecting point 37 and the second connecting point 38 use the bias voltage control point 36 as the center to be disposed symmetrically on both sides of the bias voltage control point 36.

Since the differential variable capacitor 3 is designed as a whole, therefore asymmetric coils will not occur, and we can know about the factor of overall loading quality of the variable capacitor to effectively control the overall loading quality of the variable capacitor. Further, the p-substrate at its top surface further comprises a p-type ion implant region 39 coupled to a grounding point 40 for the purpose of grounding. The first gate 34 and the second gate 35 according to a preferred embodiment of the present invention is made of a poly-silicon material.

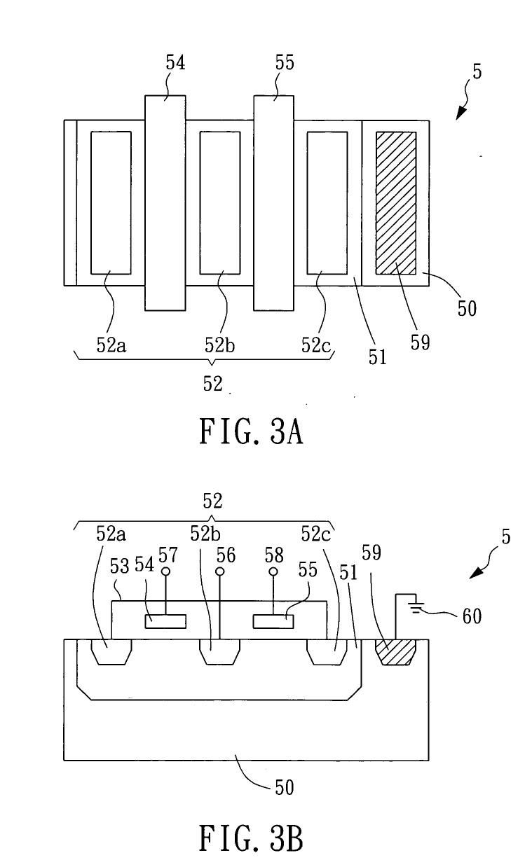

Please refer to FIGS. 3A and 3B for the top view and the cross-sectional view according to a second preferred embodiment of this invention respectively, wherein the integrated circuit of the differential variable capacity 5 forms a p-well 51 at the top surface of a n-type substrate 50 and uses at least three p-type ion implant regions 52 disposed on the top surface of the p-well 51. The three p-type ion implant regions 52 include a first p-type ion implant region 52a, a second p-type ion implant region 52b, and a third p-type ion implant region 52c, wherein the first p-type ion implant region 52a and the third p-type ion implant region 52c use the second p-type ion implant region 52b as the center to be disposed symmetrically on both sides of the second p-type ion implant region 52b. Since the positions of the first p-type ion implant region 52a, the second p-type ion implant region 52b, and the third p-type ion implant region 52c are confirmed during the ion implantation, so that the differential variable capacitor 5 is designed as a whole, and does not require repositioning for the symmetrical connection at a later manufacturing process.

The conventional lithographic and etching technologies are used to form a structure using the contact point of an oxide layer to connect the connecting points and metal wire; wherein the metal wire 53 connects the foregoing at least three p-type ion implant points 52; the first gate 54 is disposed in the metal wire 53 and between the first p-type ion implant region 52a and the second p-type ion implant region 52b; the second gate 55 is also disposed in the metal wire 53 and between the second p-type ion implant region 52b and the third p-type ion implant region 52c. The bias voltage control point 56 is coupled to the first p-type ion implant region 52a, the second p-type ion implant region 52b, and the third p-type ion implant region 52c; the first connecting point 57 is coupled to the first gate 54; the second connecting point 58 is coupled to the second gate 55, wherein the first connecting point 57 and the second connecting point 58 use the bias voltage control point 56 as the center to be disposed symmetrically on both sides of the bias voltage control point 56, which are also the first gate 54 and the second gate 55 and use the bias voltage control point 56 as the center to be disposed symmetrically on both sides of the bias voltage control point 56.

Further, the n-type substrate 50 at its top surface comprises an n-type ion implant region 59 coupled to a grounding point 60 for the purpose of grounding. The differential variable capacitor 5 is also designed as a whole, which has the same effect as the first preferred embodiment, and thus will not be described here.

In view of the description above, the present invention discloses an integrated circuit design of a differential variable capacitor, which is applicable for both the n-type semiconductor substrate and the p-type semiconductor substrate. The present invention uses an integrated method to design an integrated circuit of the differential variable capacitor to effectively reduce the chip size and lower the manufacturing cost. The present invention can prevent asymmetrical coils, and allows us to know about the factor of overall loading quality of the variable capacitor, and further effectively control the overall loading quality of the variable capacitor.

1. An integrated circuit for differential variable capacitors, comprising:
a p-substrate;
an n-well region, disposed at the top surface of said p-substrate;
at least three n-type ion implant regions, each disposed on the top surface of said n-well region;
a metal wire, for connecting said at least three n-type ion implant regions;
a bias voltage control terminal, coupled to said n-type ion implant region;
a first gate; and
a second gate, being coupled to said first gate.

2. The integrated circuit for differential variable capacitors of claim 1, wherein said first gate and second gate are disposed symmetrically on opposite side of said voltage control terminal in respective.

3. The integrated circuit for differential variable capacitors of claim 1, wherein said first gate is made of a polysilicon.

4. The integrated circuit for differential variable capacitors of claim 1, wherein said second gate is made of a polysilicon.

5. The integrated circuit for differential variable capacitors of claim 1, wherein said p-substrate further comprises a p-type ion implant region arranged at the top surface thereof.

6. The integrated circuit for differential variable capacitors of claim 5, wherein said p-type ion implant region is coupled to a grounding terminal.

7. An integrated circuit for differential variable capacitors, comprising:
an n-type substrate;
a p-type well region, disposed on the top surface of said n-type substrate;
at least three p-type ion implant regions, each disposed on the top surface of said p-type well region;
a metal wire, for connecting said at least three p-type ion implant regions;
a bias voltage control terminal, coupled to said p-type ion implant regions;
a first gate; and
a second gate, being coupled to said first gate.

8. The integrated circuit for differential variable capacitors of claim 7, wherein said first and second gates are disposed symmetrically on both sides of said bias voltage control terminal.

9. The integrated circuit for differential variable capacitors of claim 7, wherein said first gate is made of a polysilicon.

10. The integrated circuit for differential variable capacitors of claim 7, wherein said second gate is made of a polysilicon.

11. The integrated circuit for differential variable capacitors of claim 7, wherein said n-type substrate further comprises an n-type ion implant region arranged at the top surface thereof.

12. The integrated circuit for differential variable capacitors of claim 11, wherein said n-type ion implant region is coupled to a grounding ternimal.
